(19) United States
(12) Patent Application Publication
(10) Pub. No.: US 2016/0365465 A1
(43) Pub. Date: Dec. 15, 2016

(54) SENSOR AND MANUFACTURING METHOD OF SENSOR

(71) Applicant: Au Optronics Corporation, Hsinchu (TW)

(72) Inventors: Zao-Shi Zheng, Kaohsiung City (TW); Ying-Hsien Chen, Kaohsiung City (TW); Wen-Bin Hsu, Miaoli County (TW)

(21) Appl. No.: 14/845,302

(22) Filed: Sep. 4, 2015

(30) Foreign Application Priority Data
Jun. 10, 2015 (TW) 104118752

(51) Int. Cl. H01L 31/0224; H01L 31/0216; H01L 27/146; H01L 31/18; H01L 31/0232

(52) U.S. Cl. CPC H01L 31/022408; H01L 31/18; H01L 31/02322; H01L 27/14663; H01L 31/02164; H01L 27/14685

(57) ABSTRACT

A manufacturing method of a sensor including the following steps and a sensor are provided. An active device and a first insulation layer covering the active device are formed on a substrate. The first insulation layer has a first opening exposing a portion of the active device. A blanket conductive layer is formed on the first insulation layer using a conductive material. The blanket conductive layer is connected to the active device through the first opening. A photoelectric conversion material layer is formed on the blanket conductive layer. A first photoresist pattern formed on photoelectric conversion material layer is served as a mask for patterning the photoelectric conversion material layer into a photoelectric conversion unit. The blanket conductive layer is patterned to form a first electrode disposed in the first opening and electrically connecting the photoelectric conversion unit to the active device.

### CROSS-REFERENCE TO RELATED APPLICATION

This application claims the priority benefit of Taiwan application serial no. 104118752, filed on Jun. 10, 2015. The entirety of the above-mentioned patent application is hereby incorporated by reference herein and made a part of this specification.

### BACKGROUND OF THE INVENTION

Field of the Invention

The invention relates to a sensor and a manufacturing method of the sensor, and more particularly, to a photosensor and a manufacturing method of such type of sensors.

Description of Related Art

In recent years, with the development in optoelectronics technology, the application of a sensor has become more extensive, and the sensing capability and the sensing quality of the sensor have also increased. For example, the medical application and development of a sensor capable of sensing X-ray are both relatively vigorous due to convenience and good image quality thereof. To achieve better sensing quality or to sense dynamic images, higher performance is demanded for the transistor (or active device) in the sensor. In general, the active device in the sensor can adopt an amorphous silicon material as a channel layer, but the carrier mobility of the amorphous silicon material is not high enough for effectively sensing dynamic images. Therefore, an oxide semiconductor can be used instead as the channel layer in the active device of the sensor. The sensing of dynamic images is achieved via the characteristic of higher carrier mobility of the oxide semiconductor.

For example, a sensor for light sensing application needs a sensing structure composed of a photoelectric conversion material formed on an active device, so as to convert received light into an electric signal. In such an application, hydrogen is used in the forming process of the photoelectric conversion material, and the diffusion of hydrogen may cause variation to the characteristics of the oxide semiconductor. Therefore, a high performance sensor still has room for improvement.

### SUMMARY OF THE INVENTION

The invention provides a manufacturing method of a sensor capable of reducing variation generated to an active device in the sensor from the influence of a subsequent process.

The invention provides a sensor having ideal quality.

A manufacturing method of a sensor of the invention includes the following steps. An active device is formed on a substrate. A first insulation layer is formed on the substrate to cover the active device, wherein a first opening is formed in the first insulation layer to partially expose the active device. A blanket conductive layer is formed on the first insulation layer using a conductive material, wherein the blanket conductive layer is connected to the active device through the first opening. A photoelectric conversion material layer is formed on the blanket conductive layer. A first photoresist pattern is formed on photoelectric conversion material layer and the photoelectric conversion material layer is patterned into a photoelectric conversion unit by using the first photoresist pattern as a mask. The blanket conductive layer is patterned to form a first electrode, wherein the first electrode is disposed in the first opening and electrically connects the photoelectric conversion unit to the active device.

A sensor of the invention includes an active device, a first insulation layer, a first electrode, a photoelectric conversion unit, and a light-shielding layer. The active device is disposed on the substrate. The first insulation layer is disposed on the substrate and has a first opening to partially expose the active device. The first electrode covers the first opening, wherein the first electrode is disposed on the first insulation layer and is filled in the first opening, and the area of the first electrode is greater than the area of the first opening. The photoelectric conversion unit is disposed on the first electrode and electrically connected to the first electrode. The light-shielding layer is disposed above the active device.

Based on the above, the manufacturing method of a sensor of an embodiment of the invention can reduce the diffusion of process gas to a channel layer of an active device during the forming process of a photoelectric conversion material, such that variation to the channel layer during the manufacturing process can be mitigated. Therefore, the sensor of an embodiment of the invention has ideal quality.

In order to make the aforementioned features and advantages of the disclosure more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1F are a manufacturing method of a sensor of the first embodiment of the invention.

FIG. 2A to FIG. 2C are a manufacturing method of a sensor of the second embodiment of the invention.

FIG. 3A to FIG. 3C are a manufacturing method of a sensor of the third embodiment of the invention.

FIG. 4 is a schematic of a sensor of the fourth embodiment of the invention.

FIG. 5 is a schematic of a sensor of the fifth embodiment of the invention.

FIG. 6 is a schematic of a sensor of the sixth embodiment of the invention.

### DESCRIPTION OF THE EMBODIMENTS

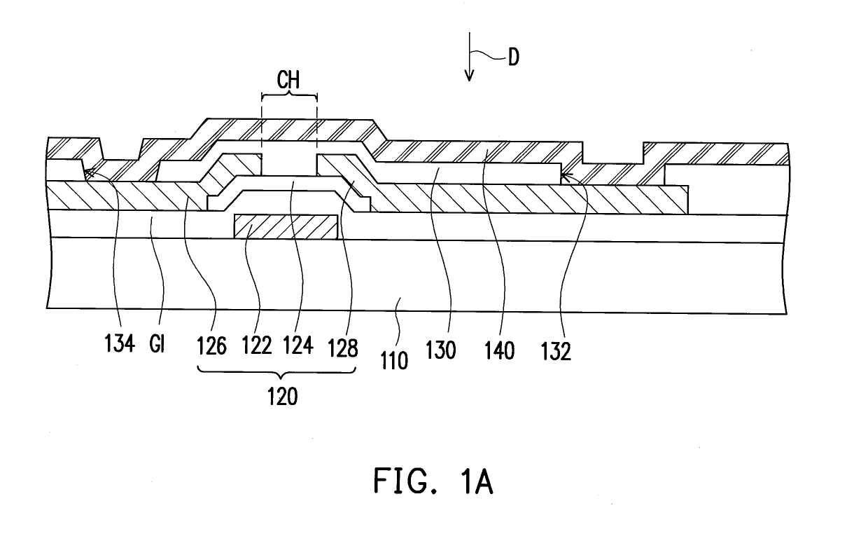

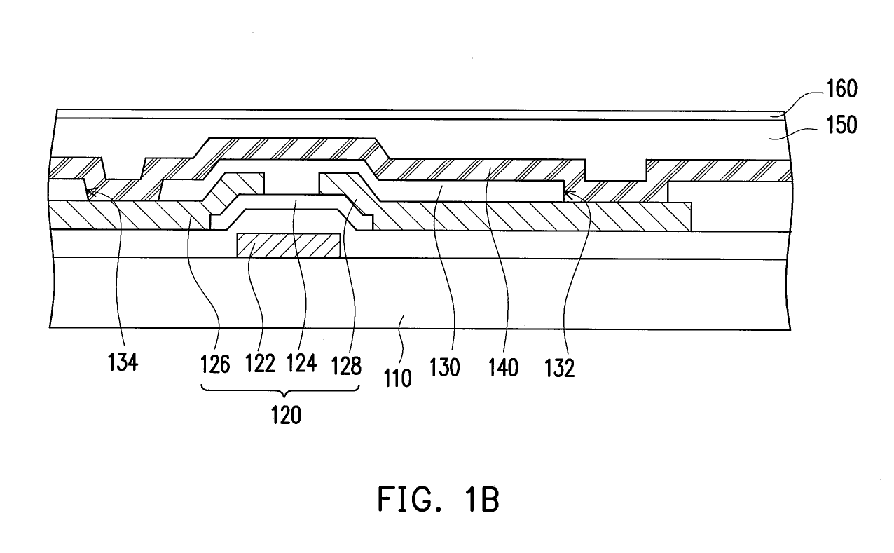

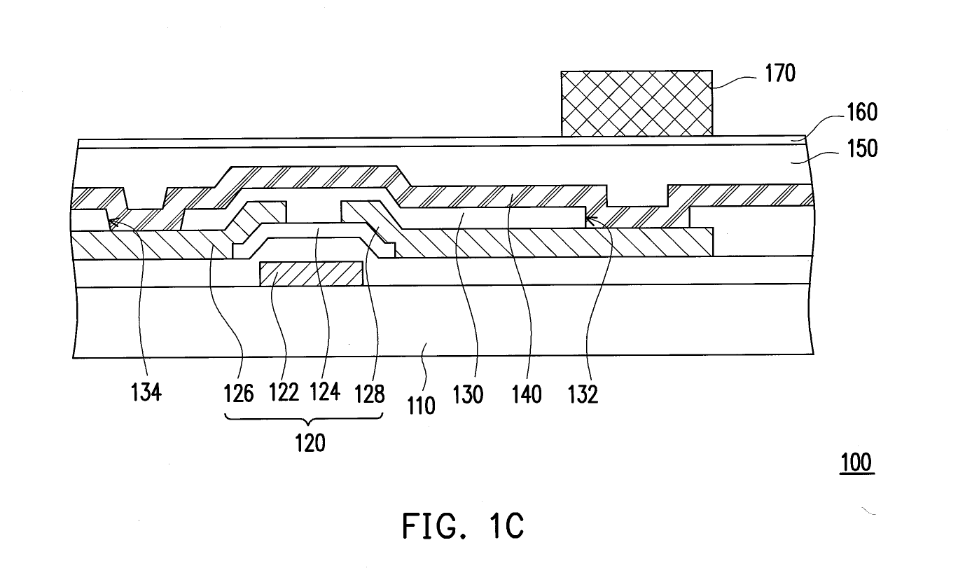

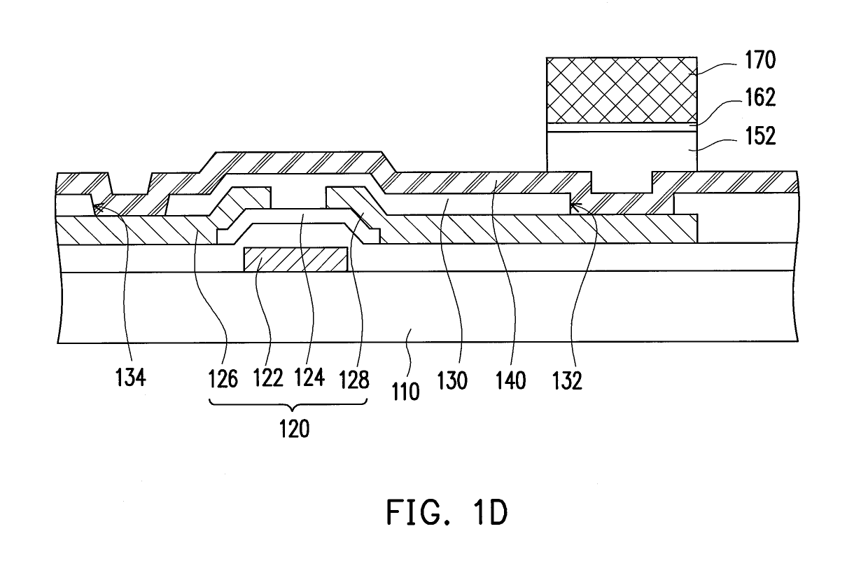

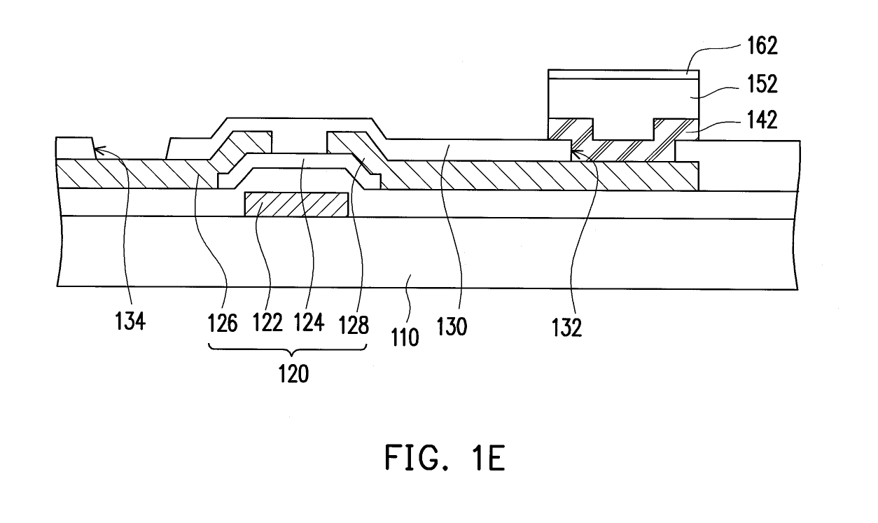

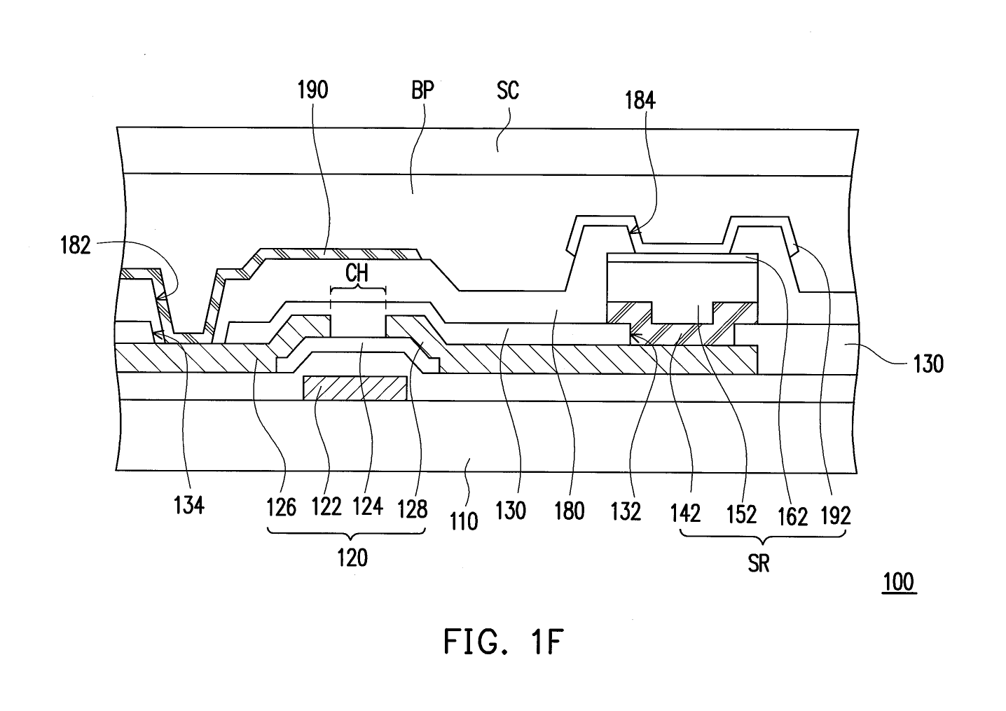

FIG. 1A to FIG. 1F are a manufacturing method of a sensor of the first embodiment of the invention. First, it can be known from FIG. 1A that, an active device 120 is formed on a substrate 110, wherein the active device 120 in the present embodiment is, for instance, a thin-film transistor, and the active device 120 includes a gate 122, a channel layer 124, a source 126, and a drain 128. The gate 122 is located between the channel layer 124 and the substrate 110, and a gate insulation layer GI is disposed between the gate 122 and the channel layer 124 to prevent direct conduction between the two. Moreover, the source 126 and the drain 128 are both in contact with the channel layer 124 and are separated by a distance on the channel layer 124 to define a channel region CH. The bottom-gate structure adopted for the structural design of the active device 120 is only an illustration, and is not intended to limit the invention. In other embodiments, the active device 120 can have the design of a top-gate structure, and the relative disposition relationship of the gate 122, the channel layer 124, the source 126, and the drain 128 can adopt a different design. Any design in which in the active device 120, carriers are allowed transmitting in the channel layer 124 through the control of the gate 122 to electrically conduct the source 126 and the drain 128 can be adopted.

The manufacturing method of the gate 122, the channel layer 124, the source 126, the drain 128, and the gate insulation layer GI includes a film layer deposition step (such as chemical vapor deposition, physical vapor deposition, or thin-film coating), a patterning step (such as a photolithoetching step, a laser etching step, or a stripping step), or a combination of the steps. Moreover, in the present embodiment, the material of each of the gate 122, the source 126, and the drain 128 can be a conductive material including, for instance, various metals, conductive metal oxides, and organic conductive materials. The gate 122, the source 126, and the drain 128 can each be formed by a single conductive material or alloy or formed by the laminate of a plurality of conductive materials or alloys. The material of the channel layer 124 is, for instance, an oxide semiconductor, and includes, for instance, indium gallium zinc oxide (IGZO), indium zinc oxide (IZO), indium gallium oxide (IGO), zinc oxide (ZnO), cadmium oxide.germanium oxide (2CdO.GeO₂), nickel cobalt oxide (NiCo₂O₄), or a combination of the materials. The oxide semiconductor itself has ideal carrier mobility, thus helping to enhance the performance of the active device 120. The material of the gate insulation layer GI includes silicon oxide, silicon nitride, aluminum oxide, an organic insulation material, or a combination of the materials.

Next, referring further to FIG. 1A, a first insulation layer 130 is formed on the substrate 100 to cover the active device 120. In the present embodiment, the first insulation layer 130 has an opening 132 and an opening 134. The opening 132 exposes a partial area of the drain 128 and the opening 134 exposes a partial area of the source 126, but the invention is not limited thereto. In other embodiments, the opening 134 can be omitted or manufactured in a subsequent manufacturing step. The material of the first insulation layer 130 can be an organic or inorganic insulation material, and the first insulation layer 130 can be formed by stacking a plurality of insulation material layers or formed by a single insulation material layer.

After the first insulation layer 130 is formed, a blanket conductive layer 140 is formed on the first insulation layer 130 by using a conductive material. The material of the blanket conductive layer 140 can be a metal such as titanium or molybdenum. Here, the area of the blanket conductive layer 140 is substantially the same as the substrate 110 and the blanket conductive layer 140 is a conductive layer completely and continuously formed on the substrate 110. In other words, the blanket conductive layer 140 is a conductive layer that is not patterned after being formed on the substrate 110 via a deposition step, and therefore if the semifinished product of FIG. 1A is viewed from a top view direction D, the blanket conductive layer 140 fills the entire area such that other elements or components cannot be viewed from a top view direction D. Moreover, the blanket conductive layer 140 can be in contact with the drain 128 through the opening 132 of the first insulation layer 130 and be in contact with the source 126 through the opening 134.

Then, referring to FIG. 1B, a photoelectric conversion material layer 150 is formed on the blanket conductive layer 140 and a transparent conductive material layer 160 is optionally formed on the blanket conductive layer 140, wherein the photoelectric conversion material layer 150 is located between the transparent conductive material layer 160 and the blanket conductive layer 140. Here, the material of the photoelectric conversion material layer 150 is mainly silicon, and the photoelectric conversion material layer 150 includes a first-type semiconductor material layer, an intrinsic semiconductor material layer, and a second-type semiconductor material layer stacked in order, and one of the first-type semiconductor material layer and the second-type semiconductor material layer is a p-type semiconductor material, and the other is an n-type semiconductor material. The material of the transparent conductive material layer 160 includes a conductive oxide, a conductive organic material, or a combination of the materials. For instance, the conductive oxide includes indium tin oxide, indium zinc oxide, tin oxide, zinc oxide, indium oxide, or a combination of the materials.

Hydrogen is generally needed in the forming process of the photoelectric conversion material layer 150. If hydrogen diffuses to the channel layer 124 formed by an oxide semiconductor, the electrical characteristics of the channel layer 124 could be changed, thus causing variation to the device characteristics of the active device 120. However, in the forming process of the photoelectric conversion material layer 150 of the present embodiment, since the blanket conductive layer 140 continuously covers the entire area of the substrate 110 and the blanket conductive layer 140 is formed of a dense material layer, the blanket conductive layer 140 can block hydrogen from diffusing to the channel layer 124. Therefore, variation to the characteristics of the active device 120 due to the manufacturing process of the photoelectric conversion material layer 150 can be mitigated or restrained. In other words, the forming process of the photoelectric conversion material layer 150 is performed in the presence of the blanket conductive layer 140, thus helping to ensure the device characteristics of the active device 120.

Then, referring to FIG. 1C, after the photoelectric conversion material layer 150 is formed, a photoresist pattern 170 is formed on the photoelectric conversion material layer 150, and the photoelectric conversion material layer 150 is patterned by using the photoresist pattern 170 as a mask. In the present embodiment, a transparent conductive material layer 160 is further disposed on the photoelectric conversion material layer 150, and therefore in the patterning process of the photoelectric conversion material layer 150, the transparent conductive material layer 160 is also patterned. The area of the photoresist pattern 170 at least covers the area of the opening 132. Specifically, the covering area and the disposition position of the photoresist pattern 170 can be adjusted according to the demand of the design for the sensing area of the sensor. In FIG. 1C, although the photoresist pattern 170 is illustrated to be substantially corresponding to the opening 132, the invention is not limited thereto.

Referring to FIG. 1D, after the patterning step of FIG. 1C is performed, a photoelectric conversion unit 152 and a transparent conductive layer 162 are formed. At this point, the photoelectric conversion unit 152 can include a first-type semiconductor layer, an intrinsic semiconductor layer, and a second-type semiconductor layer stacked in order, and one of the first-type semiconductor layer and the second-type semiconductor layer is a p-type semiconductor layer, and the other is an n-type semiconductor layer. The blanket conductive layer 140 still covers the entire surface of the substrate 110. Therefore, to pattern the blanket conductive layer 140 into the desired outline, in the present embodiment, the blanket conductive layer 140 can further be patterned by using the photoresist pattern 170 as a mask, and then the photoresist pattern 170 is removed to form a first electrode 142 in FIG. 1E. In other words, in the steps of FIG. 1C and FIG. 1D, the same photoresist pattern 170 is used for defining the outline of each of the photoelectric conversion unit 152 and the first electrode 142. Therefore, in the present embodiment, the outlines of the photoelectric conversion unit 152 and the first electrode 142 are substantially the same, or are conformal to each other. Moreover, it can be known from FIG. 1E that, the conductive material of the blanket conductive layer filled in the opening 134 of the first insulation layer 130 is removed, and therefore the source 126 of the active device 120 is exposed at this point.

Then, referring to FIG. 1F, after the outlines of the photoelectric conversion unit 152 and the first electrode 142 are defined, a second insulation layer 180 can be formed on the photoelectric conversion unit 152, wherein the second insulation layer 180 has an opening 182 corresponding to the opening 134, and the opening 182 at least exposes a portion of the source 126 exposed by the opening 134. In other words, the opening 182 at least exposes a portion of the source 126. Here, the opening 182 and the opening 134 are formed by different patterning processes, but are not limited thereto. In other embodiments, the opening 134 is not formed when the first insulation layer 130 is formed by performing the step of FIG. 1A, and instead the opening 134 and the opening 182 can be formed via the same patterning step when the second insulation layer 180 is formed. At this point, the sidewalls of the opening 134 and the opening 182 are connected to each other to form an even sidewall defining the opening exposing the source 126.

In the present embodiment, a light-shielding layer 190 is further formed on the second insulation layer 180, and the light-shielding layer 190 can be filled in the opening 182 to be in contact with the source 126. The light-shielding layer 190 can be manufactured via a conductive material having light-shielding properties, and therefore the light-shielding layer 190 filled in the opening 182 can be electrically connected to the source 126 and not be electrically floated above the active device 120. More specifically, the area of the light-shielding layer 190 at least shields the channel region CH, and therefore the channel region CH is not readily irradiated by external light, thus helping to ensure that the channel layer 124 maintains stability properties.

It can be known from FIG. 1F that, in addition to the opening 182, the opening 184 is also formed in the second insulation layer 180, and the opening 184 corresponds to the area of the photoelectric conversion unit 152. Moreover, a second electrode 192 is filled in the opening 184, such that the second electrode 192 is in contact with the transparent conductive layer 162 in the opening 184 and can be electrically connected to the photoelectric conversion unit 152. In general, the second electrode 192 is connected to a common potential. In an alternative embodiment, the second electrodes 192 connected to different photoelectric conversion units 152 on the entire substrate 110 can be connected together and further connected to the common potential. In other embodiments, the transparent conductive layer 162 disposed above the photoelectric conversion unit 152 can be optionally omitted, such that the second electrode 192 is in contact with the photoelectric conversion unit 152. In other words, in the present embodiment, a sensing structure SR can be formed by sandwiching the photoelectric conversion unit 152 between the first electrode 142 and the second electrode 192, and the sensing structure SR is adapted to convert the received light energy into an electric signal, and the electric signal converted by the sensing structure SR can be transmitted to the outside through the active device 120 to achieve light-sensing function.

To protect the sensing structure SR, a protective layer BP is further formed on the substrate 110 to cover the sensing structure SR. At the same time, if the sensing structure SR is to be applied in the field of X-ray sensing, a scintillator layer SC can be further formed above the protective layer BP, and the material of the scintillator layer SC can be cesium iodide or thallium iodide, but the invention is not limited thereto. Specifically, it can be known from FIG. 1F that, the sensor 100 mainly includes the active device 120, the first insulation layer 130, the first electrode 142, the photoelectric conversion unit 152, the second insulation layer 180, the light-shielding layer 190, and the second electrode 192 disposed on the substrate 110. The active device 120 is disposed on the substrate 110. The first insulation layer 130 is disposed on the substrate 110 and has the opening 132 and the opening 134. The first electrode 142 covers the opening 132. The photoelectric conversion unit 152 is disposed on the first electrode 142 and electrically connected to the first electrode 142. The light-shielding layer 190 is disposed above the active device 120, and the light-shielding layer 190 at least shields the area of the channel region CH. The second insulation layer 180 is disposed on the first insulation layer 130. The photoelectric conversion unit 152 is located between the first insulation layer 130 and the second insulation layer 180. The second insulation layer 180 has the opening 182 and the opening 184. The opening 182 at least partially exposes a portion of the source 126 exposed by the opening 134, and the opening 184 corresponds to the photoelectric conversion unit 152. The light-shielding layer 190 is disposed on the second insulation layer 180, and covers the opening 182 to be electrically connected to the source 126. The second electrode 192 is in the opening 184 and is electrically connected to the photoelectric conversion unit 152.

It can be known from the manufacturing method of FIG. 1A to FIG. 1F that, the channel layer 124 in the active device 120 is manufactured by using an oxide semiconductor material, and therefore the active device 120 has ideal characteristics, such that the application of the sensor 100 can be widened, such as the sensor 100 can be applied in the sensing of dynamic images. At the same time, in the present embodiment, although hydrogen is used in the forming process of the photoelectric conversion material, under the disposition of the blanket conductive layer 140 (as shown in FIG. 1B), the hydrogen in the manufacture does not readily diffuse to the oxide semiconductor. Therefore, although the photoelectric conversion unit 152 is manufactured after the channel layer 124 is formed, the process gas used to form the photoelectric conversion unit 152 does not affect the characteristics of the channel layer 124, such that the active device 120 has ideal device characteristics. Moreover, the channel region CH in the sensor 100 of the present embodiment is shielded by the light-shielding layer 190, thus helping to prevent irradiation to the channel region CH by external light and ensuring the stability of the channel layer 130.

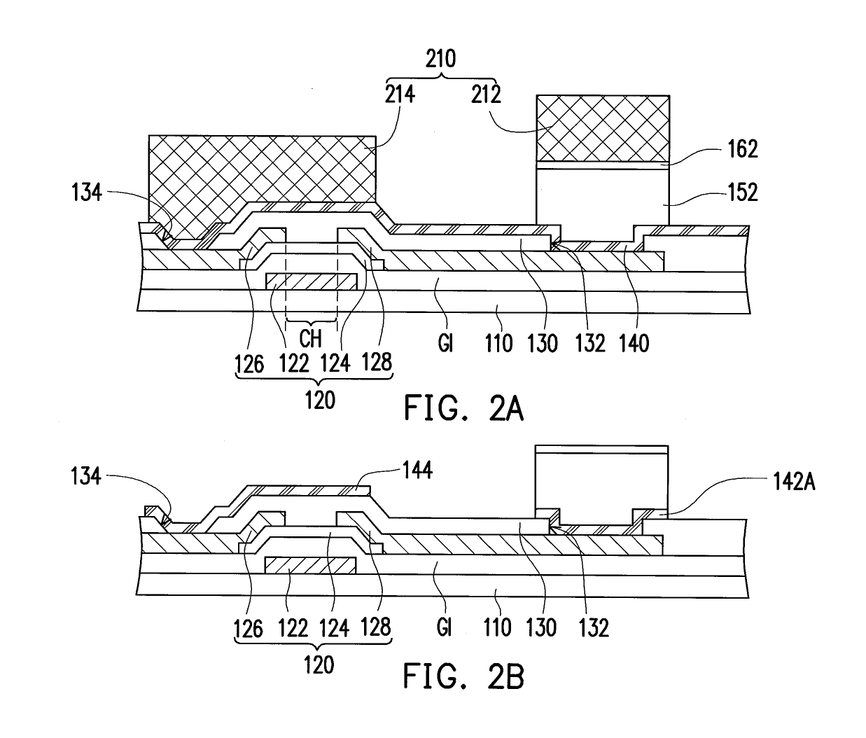

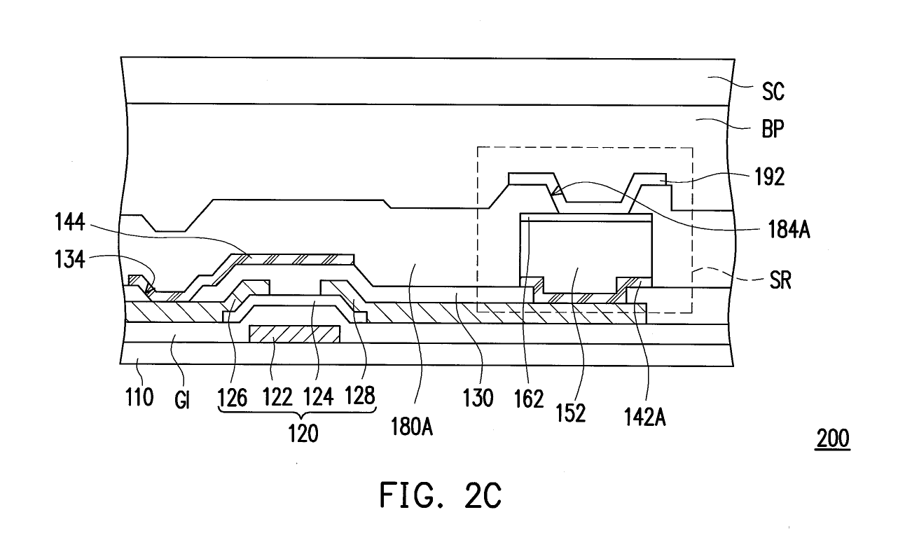

FIG. 2A to FIG. 2C are a manufacturing method of a sensor of the second embodiment of the invention. In the present embodiment, the manufacturing steps of FIG. 1A to FIG. 1D in the first embodiment can be first performed. Therefore, in the present embodiment, the characteristics of the active device 120 are not readily affected by a subsequent manufacturing step, such that the desired quality can be ensured. In other words, similarly to the first embodiment, the present embodiment can alleviate the situation in which the manufacturing process of the photoelectric conversion material affects the oxide semiconductor characteristics. Moreover, in the first embodiment, the manufacturing steps of FIG. 1A to FIG. 1D and related descriptions can all be adopted in the present embodiment.

Referring to FIG. 2A, in the present embodiment, after the manufacture of the photoelectric conversion unit 152 is complete, another photoresist pattern 210 is formed on the substrate 110, and the photoresist pattern 210 includes a first pattern region 212 located on the photoelectric conversion unit 152 and a second pattern region 214 located on the active device 120. Specifically, the area of the first pattern region 212 can be substantially the same as the area of the photoelectric conversion unit 152, and the area of the second pattern region 214 at least covers the opening 134 of the first insulation layer 130 and the channel region CH.

In the present embodiment, the first pattern region 212 can be the same as the photoresist pattern 170 of FIG. 1D. In other words, after the step of FIG. 1D is performed, the photoresist pattern 170 originally in FIG. 1D does not need to be removed, and the second pattern region 214 is directly formed on the substrate 110 having the photoresist pattern 170, such that the original photoresist pattern 170 is used as the first pattern region 212 in FIG. 2A. Alternatively, after the step of FIG. 1D is complete, the photoresist pattern 170 in FIG. 1D is first removed, and then the photoresist pattern 210 is formed with a new photoresist material layer.

Then, the blanket conductive layer 140 is patterned by using the first pattern region 212 and the second pattern region 214 as a mask. As shown in FIG. 2B, the blanket conductive layer 140 is patterned into a first electrode 142A and a light-shielding layer 144, wherein the first electrode 142A corresponds to the first pattern region 212 and the light-shielding layer 144 corresponds to the second pattern region 214. The outline and the dimension of the first electrode 142A are defined by the first pattern region 212, and therefore under the design of the present embodiment, since the area of the first pattern region 212 substantially corresponds to the area of the photoelectric conversion unit 152, the area of the first electrode 142A can be designed to be close to the area of the first electrode 142 in the first embodiment.

It can be known from the description of the first embodiment that, the blanket conductive layer 140 can be manufactured by using a metal material, and most metal materials have light-shielding characteristics. Therefore, the light-shielding layer 144 corresponding to the second pattern region 214 can provide light-shielding effect so as to block irradiation to the channel region CH by external light, thus allowing the active device 120 to have stable device characteristics.

Then, referring to FIG. 2C, a second insulation layer 180A, a second electrode 192, a protective layer BP, and a scintillator layer SC are formed on the substrate 110 in order. The second insulation layer 180A covers the photoelectric conversion unit 152 and has an opening 184A to expose the transparent conductive layer 162 on the photoelectric conversion unit 152. The second electrode 192 can be filled in the opening 184A to be in contact with the transparent conductive layer 162 such that the second electrode 192 is electrically connected to the photoelectric conversion unit 152. However, in other embodiments, the transparent conductive layer 162 can be omitted, such that the opening 184A exposes the photoelectric conversion unit 152 and the second electrode 192 is in contact with the photoelectric conversion unit 152. Accordingly, the sensing structure SR can be formed by sandwiching the photoelectric conversion unit 152 between the first electrode 142 and the second electrode 192, and the sensing structure SR is adapted to convert the received light energy into an electric signal, and the electric signal converted by the sensing structure SR can be transmitted to the outside through the active device 120 to achieve light-sensing function. Moreover, the protective layer BP covers the sensing structure SR and can protect the sensing structure SR. The scintillator layer SC is disposed on the protective layer BP and can be used to achieve the application of X-ray sensing, but the invention is not limited thereto. In other embodiments, the protective layer BP and the scintillator layer SC can be optionally omitted or replaced by other components.

Specifically, a sensor 200 of the present embodiment mainly includes the active device 120, the first insulation layer 130, the first electrode 142A, the light-shielding layer 144, the photoelectric conversion unit 152, the transparent conductive layer 162, the second insulation layer 180, and the second electrode 192 disposed on the substrate 110. The disposition relationship, the material, and the characteristics of the active device 120, the first insulation layer 130, the first electrode 142A, the photoelectric conversion unit 152, the transparent conductive layer 162, the second insulation layer 180, and the second electrode 192 are substantially the same as the descriptions of the first embodiment, and are not repeated herein.

It can be known from the manufacturing steps of FIG. 2A and FIG. 2B that, the light-shielding layer 144 and the first electrode 142A of the present embodiment are obtained by patterning the same film layer (i.e., the blanket conductive layer 140). Therefore, an additional manufacturing step is not needed for the disposition of the light-shielding layer 144, and therefore the manufacturing process of the sensor 200 can be simplified. Moreover, the light-shielding layer 144 is located between the first insulation layer 130 and the second insulation layer 180A and is electrically connected to the source 126 through the opening 134. Therefore, the light-shielding layer 144 is a non-electrically floating conductive component capable of providing light-shielding effect. Moreover, different from the first embodiment, an opening structure corresponding to the opening 134 does not need to be disposed in the second insulation layer 180A of the present embodiment.

In the present embodiment, the blanket conductive layer 140 is patterned only after the manufacture of the photoelectric conversion unit 152 is complete, and variation to the active device 120 of the sensor 200 from the manufacturing process of the photoelectric conversion unit 152 does not readily occur. Moreover, the light-shielding layer 144 can shield the channel region CH to prevent variation to the device characteristics of the active device 120 due to irradiation from external light. Therefore, the active device 120 of the sensor 200 has ideal quality and stability. Moreover, the light-shielding layer 144 of the present embodiment can be obtained by patterning the blanket conductive layer 140, and an additional manufacturing process is not needed for the manufacture, and therefore the manufacturing method of the present embodiment can help to simplify the manufacturing process.

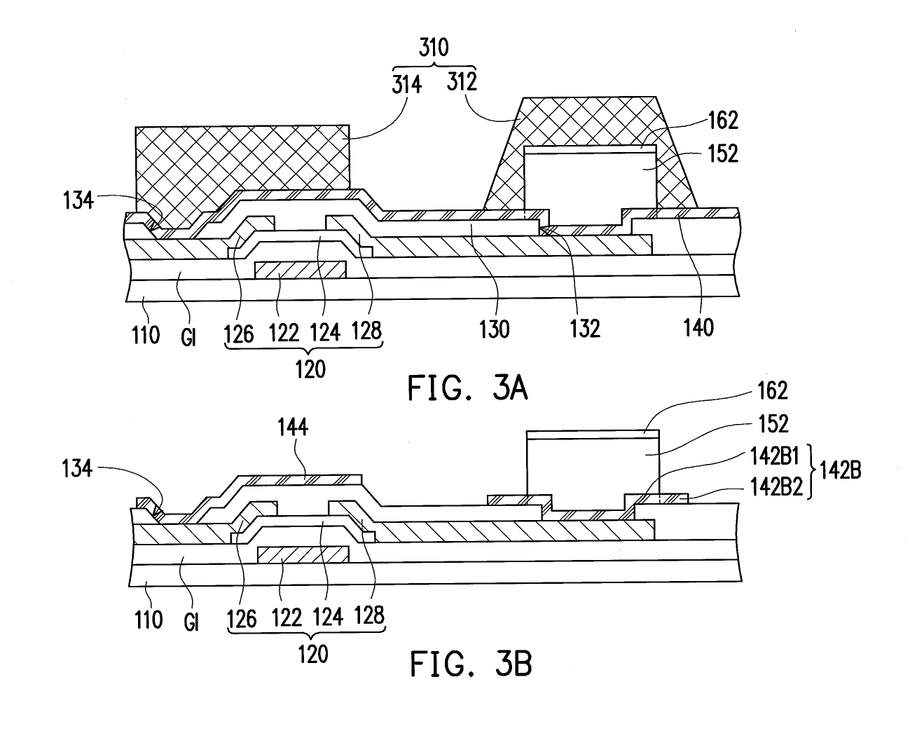

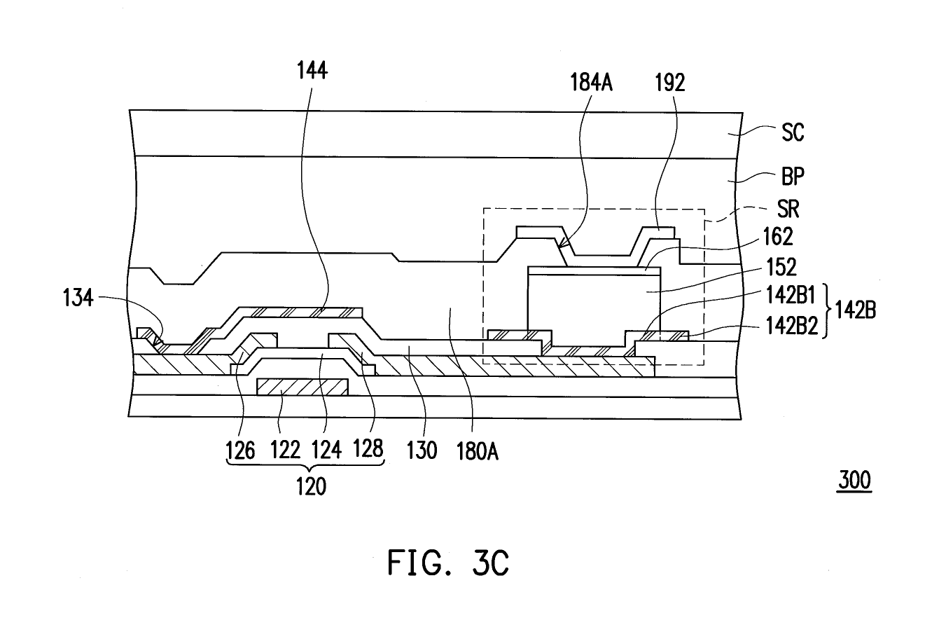

FIG. 3A to FIG. 3C are a manufacturing method of a sensor of the third embodiment of the invention. In the present embodiment, the manufacturing steps of FIG. 1A to FIG. 1D in the first embodiment can be first performed. Therefore, in the present embodiment, the characteristics of the active device 120 are not readily affected by a subsequent manufacturing step, such that the desired quality can be ensured. In other words, similar to the first embodiment, the present embodiment can prevent the phenomenon in which the manufacturing process of the photoelectric conversion material affects the oxide semiconductor characteristics. Moreover, in the first embodiment, the manufacturing steps of FIG. 1A to FIG. 1D and related descriptions can all be adopted in the present embodiment.

Referring to FIG. 3A, in the present embodiment, after the manufacture of the photoelectric conversion unit 152 is complete, the photoresist pattern 170 in FIG. 1D is first removed, and then another photoresist pattern 310 is formed on the substrate 110, and the photoresist pattern 310 includes a first pattern region 312 located on the photoelectric conversion unit 152 and a second pattern region 314 located on the active device 120. Specifically, the area of the first pattern region 312 is greater than the area of the photoelectric conversion unit 152, and the area of the second pattern region 314 at least covers the opening 134 of the first insulation layer 130 and the channel region CH.

Then, the blanket conductive layer 140 is patterned by using the first pattern region 312 and the second pattern region 314 as a mask to form a first electrode 142B and the light-shielding layer 144 in FIG. 3B, wherein the first electrode 142B corresponds to the first pattern region 312 and the light-shielding layer 144 corresponds to the second pattern region 314. Since the area of the first pattern region 312 is greater than the area of the photoelectric conversion unit 152, the first electrode 142B includes a contact portion 142B1 and a protruding portion 142B2 connected to each other. The contact portion 142B1 is in contact with the photoelectric conversion unit 152, and the protruding portion 142B2 protrudes outward from the contact portion 142B1 and is not in contact with the photoelectric conversion unit 152. In other words, the area of the contact portion 142B1 is substantially equal to the area of the photoelectric conversion unit 152, and the protruding portion 142B2 surrounds the outline of the photoelectric conversion unit 152. If a light is cast in the thickness direction of the substrate 110, the projections of the protruding portion 152B2 and the contact portion 142B1 are not overlapped.

In the present embodiment, when the first electrode 142B is manufactured, the manufacture of the light-shielding layer 144 is completed at the same time, thus helping to simplify the manufacturing process. Moreover, the light-shielding layer 144 is substantially the same as the light-shielding layer 144 of the second embodiment, and can be electrically connected to the source 126 of the active device 120 through the opening 134. Therefore, the conductive light-shielding layer 144 is not electrically floating.

Then, referring to FIG. 3C, the second insulation layer 180A, the second electrode 192, the protective layer BP, and the scintillator layer SC are formed on the substrate 110 in order. The second insulation layer 180A covers the photoelectric conversion unit 152 and has the opening 184A to expose the transparent conductive layer 162 on the photoelectric conversion unit 152. The second electrode 192 can be filled in the opening 184A to be in contact with the transparent conductive layer 162 such that the second electrode 192 is electrically connected to the photoelectric conversion unit 152. The protective layer BP covers the substrate 110 and can protect the sensing structure SR. The scintillator layer SC is disposed on the protective layer BP and can be used to achieve the application of X-ray sensing, but the invention is not limited thereto. It can be known from FIG. 3C that, the dimension of the first electrode 142B in the sensor 300 is greater than the dimension of the photoelectric conversion unit 152 and includes the contact portion 142B1 and the protruding portion 142B2. In addition, the manufacturing steps, the structural design, and the characteristics of the sensor 300 are all similar to those of the sensor 200 of the second embodiment, and are not repeated herein.

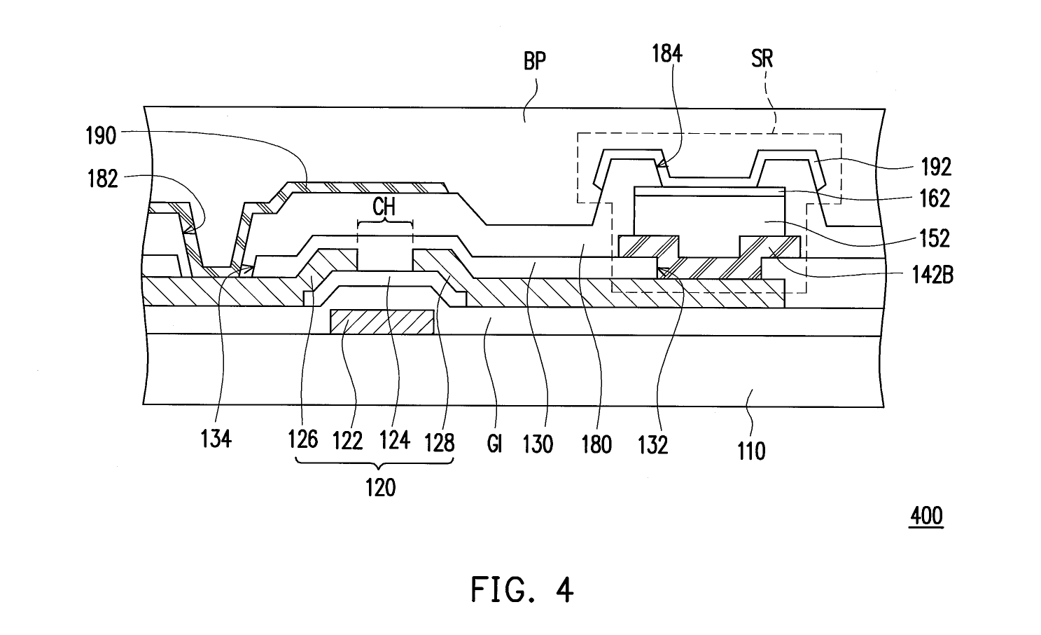

FIG. 4 is a schematic of a sensor of the fourth embodiment of the invention. Referring to FIG. 4, a sensor 400 includes the active device 120, the first insulation layer 130, the first electrode 142B, the photoelectric conversion unit 152, the transparent electrode layer 162, the second insulation layer 180, the light-shielding layer 190, the second electrode 192, and the protective layer BP. The active device 120 is disposed on the substrate 110. The first insulation layer 130 is disposed on the substrate 110 and has the opening 132 and the opening 134. The first electrode 142 covers the opening 132. The photoelectric conversion unit 152 is disposed on the first electrode 142 and electrically connected to the first electrode 142. The light-shielding layer 190 is disposed above the active device 120, and the light-shielding layer 190 at least shields the area of the channel region CH. The second insulation layer 180 is disposed on the first insulation layer 130. The photoelectric conversion unit 152 is located between the first insulation layer 130 and the second insulation layer 180. The second insulation layer 180 has an opening 182 to partially expose a portion of the source 126 exposed by the opening 134. The light-shielding layer 190 is disposed on the second insulation layer 180, and covers the opening 182 to be electrically connected to the source 126. The second electrode 192 is in contact with the transparent conductive layer 162 in the opening 184 and can be electrically connected to the photoelectric conversion unit 152. In this way, the first electrode 142B, the photoelectric conversion unit 152, and the second electrode 192 can form the sensing structure SR.

In the present embodiment, the sensor 400 can be manufactured by integrating the manufacturing method of the first embodiment and the manufacturing method of the third embodiment. In short, the manufacturing method of the sensor 400 can include first performing the manufacturing steps of FIG. 1A to FIG. 1D, and after the photoresist pattern of FIG. 1D is removed, the first pattern region 312 of FIG. 3A is formed on the substrate 110. At this point, the second pattern region 314 of FIG. 3A does not need to be formed on the substrate 110. Then, the blanket conductive layer 140 is patterned by using the first pattern region 312 as a mask to obtain the second electrode 142B. Then, the manufacturing process of FIG. 1F is performed to manufacture components such as the second insulation layer 180, the light-shielding layer 190, the second electrode 192, and the protective layer BP on the substrate 110 to form the sensor 400. Therefore, the location of disposition, the material selection, and the characteristics of each component in the sensor 400 are as described in the above embodiments. Of course, if the sensor 400 is to be applied in the filed of X-ray sensing, a scintillator layer can further be formed on the protective layer BP, but the invention is not limited thereto.

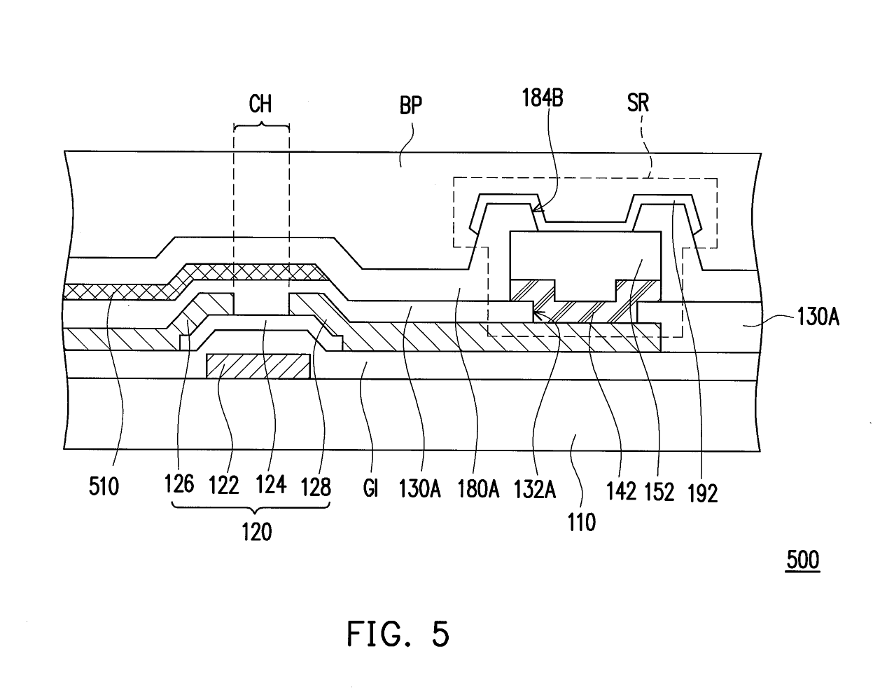

FIG. 5 is a schematic of a sensor of the fifth embodiment of the invention. Referring to FIG. 5, a sensor 500 includes the substrate 110, the active device 120, the first insulation layer 130A, the first electrode 142, the photoelectric conversion unit 152, the second insulation layer 180A, a light-shielding layer 510, the second electrode 192, and the protective layer BP. The active device 120 is disposed on the substrate 110. The first insulation layer 130A is disposed on the substrate 110 and has the opening 132A. The first electrode 142 covers the opening 132A. The photoelectric conversion unit 152 is disposed on the first electrode 142 and electrically connected to the first electrode 142. The light-shielding layer 510 is disposed on the first insulation layer 130A, is located above the active device 120, and at least shields the area of the channel region CH. The second insulation layer 180A is disposed on the first insulation layer 130A. The photoelectric conversion unit 152 is located between the first insulation layer 130A and the second insulation layer 180A. The second insulation layer 180A has an opening 184B to at least partially expose a portion of the photoelectric conversion unit 152. The light-shielding layer 190 is disposed between the first insulation layer 130A and the second insulation layer 180A. The second electrode 192 is filled in the opening 184B to be electrically connected to the photoelectric conversion unit 152. In this way, the first electrode 142, the photoelectric conversion unit 152, and the second electrode 192 can form the sensing structure SR.

In the present embodiment, the light-shielding layer 510 is not in contact with the source 126 of the active device 120. At the same time, the light-shielding layer 510 can be manufactured by a non-conductive light-shielding material such as a resin material. Moreover, the active device 120, the first insulation layer 130A, the first electrode 142, the photoelectric conversion unit 152, the second insulation layer 180A, the second electrode 192, and the protective layer BP of the present embodiment can be manufactured by any of the manufacturing methods in the above embodiments. Therefore, variation to the active device 120 due to influence from the manufacturing process of the photoelectric conversion unit 152 does not readily occur. At the same time, since the light-shielding layer 510 shields the channel region CH, variation to the device characteristics of the active device 120 due to irradiation from external light does not readily occur. Overall, the sensor 500 can have ideal quality and performance and is adapted to be applied in various fields.

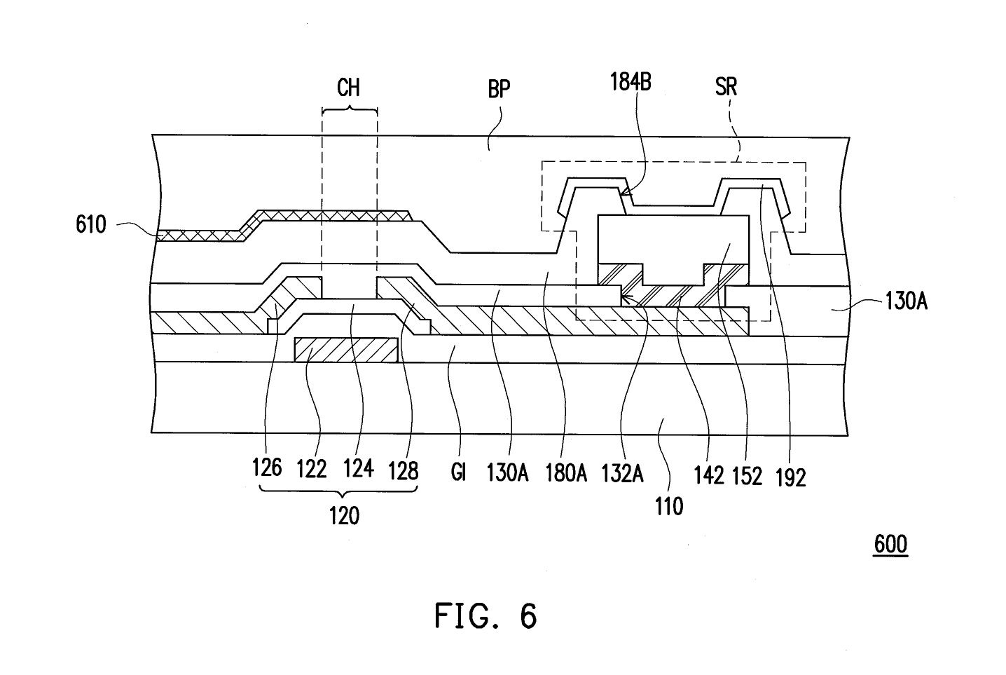

FIG. 6 is a schematic of a sensor of the sixth embodiment of the invention. Referring to FIG. 6, a sensor 600 is substantially the same as the sensor 500, and therefore, components having the same reference numerals in FIG. 5 and FIG. 6 can be cross-referenced. In the sensor 600, a light-shielding layer 610 above the active device 120 is disposed on the upper surface of the second insulation layer 180A, in other words, the second insulation layer 180A is located between the light-shielding layer 610 and the first insulation layer 130A. The light-shielding layer 610 has the same design as in the fifth embodiment, and is not in contact with the source 126 of the active device 120. At the same time, the light-shielding layer 610 can be manufactured by a non-conductive light-shielding material such as a resin material.

Based on the above, in the manufacturing method of a sensor of an embodiment of the invention, during the forming process of a photoelectric conversion layer, a blanket conductive layer is disposed on a substrate and the blanket conductive layer is located on an active device. Therefore, the presence of the blanket conductive layer helps to prevent influence to a channel layer of the active device from process gas. Even if hydrogen is used in the forming process of the photoelectric conversion layer, and an oxide semiconductor is adopted for the channel layer of the active device, the channel layer of the active device can still have the desired characteristics and not be affected by process gas. Moreover, in an embodiment of the invention, a light-shielding layer is disposed above the active device, and the area of the light-shielding layer at least shields the channel region of the active device. Therefore, when an oxide semiconductor is adopted for the manufacture of the channel layer of the active device, the device characteristics of the active device are not readily changed from irradiation to the channel region from external light. Therefore, the sensor of an embodiment of the invention has ideal stability.

1. A manufacturing method of a sensor, comprising:
forming an active device on a substrate;
forming a first insulation layer on the substrate to cover the active device, wherein a first opening is formed on the first insulation layer to partially expose the active device;
forming a blanket conductive layer on the first insulation layer using a conductive material, wherein the blanket conductive layer is connected to the active device through the first opening;
forming a photoelectric conversion material layer on the blanket conductive layer;
forming a first photoresist pattern on the photoelectric conversion material layer and patterning the photoelectric conversion material layer into a photoelectric conversion unit by using the first photoresist pattern as a mask; and
patterning the blanket conductive layer to form a first electrode, wherein the first electrode is disposed in the first opening and electrically connects the photoelectric conversion unit to the active device.

2. The method of claim 1, wherein a method of forming the first electrode comprises: further patterning the blanket conductive layer into the first electrode by using the first photoresist pattern as a mask after the photoelectric conversion material layer is patterned into the photoelectric conversion unit.

3. The method of claim 1, further forming a second photoresist pattern on the photoelectric conversion unit, and patterning the blanket conductive layer by using the second photoresist pattern as a mask to form the first electrode.

4. The method of claim 3, wherein the second photoresist pattern covers the photoelectric conversion unit, and the first electrode formed by patterning using the second photoresist pattern as the mask comprises a protruding portion and a contact portion connected to each other, wherein the contact portion is in contact with the photoelectric conversion unit, and the protruding portion protrudes outward from the contact portion and is not in contact with the photoelectric conversion unit.

5. The method of claim 1, wherein the active device comprises a gate, a source, a drain, and a channel layer, wherein the gate and the channel layer are stacked on each other in a thickness direction of the substrate, the source and the drain are respectively in contact with the channel layer, the source and the drain are separated from each other to define a channel region, the first opening exposes the drain, and the first electrode is connected to the drain through the first opening.

6. The method of claim 5, further forming a light-shielding layer, wherein the light-shielding layer is electrically connected to the source, and an area of the light-shielding layer shields the channel region of the active device.

7. The method of claim 6, further forming a second photoresist pattern, wherein the second photoresist pattern comprises a first pattern region located on the photoelectric conversion unit and a second pattern region located on the active device, and a method of patterning the blanket conductive layer comprises patterning the blanket conductive layer by using the first pattern region and the second pattern region as a mask to respectively form the first electrode and the light-shielding layer.

8. The method of claim 5, wherein the step of patterning the blanket conductive layer forms the first electrode and a light-shielding layer at the same time, and the light-shielding layer is electrically connected to the source.

9. The method of claim 5, further comprising:
forming a second opening in the first insulation layer, wherein the second opening exposes the source;
forming a second insulation layer covering the active device and the photoelectric conversion unit, wherein the second insulation layer has a third opening, and the third opening at least exposes a portion of the source exposed by the second opening; and
forming a light-shielding layer on the second insulation layer, wherein the light-shielding layer covers the third opening to be electrically connected to the source.

10. The method of claim 5, further forming a light-shielding layer, wherein an area of the light-shielding layer shields the channel region of the active device.

11. The method of claim 1, further comprising:
forming a second insulation layer covering the active device and the photoelectric conversion unit; and
forming a second electrode on the second insulation layer, wherein the second electrode is electrically connected to the photoelectric conversion unit.

12. A sensor, comprising:
an active device disposed on a substrate;
a first insulation layer disposed on the substrate and having a first opening to partially expose the active device;
a first electrode covering the first opening, wherein the first electrode is disposed on the first insulation layer and is filled in the first opening, and an area of the first electrode is greater than an area of the first opening;
a photoelectric conversion unit disposed on the first electrode and electrically connected to the first electrode; and
a light-shielding layer disposed above the active device.

13. The sensor of claim 12, wherein the active device comprises a gate, a source, a drain, and a channel layer, wherein the gate and the channel layer are stacked on each other in a thickness direction of the substrate, the source and the drain are respectively in contact with the channel layer, the source and the drain are separated from each other to define a channel region, and the first electrode is connected to the drain through the first opening.

14. The sensor of claim 13, wherein a material of the channel layer comprises an oxide semiconductor.

15. The sensor of claim 13, wherein the first insulation layer further has a second opening, the second opening exposes the source, and the light-shielding layer is electrically connected to the source through the second opening.

16. The sensor of claim 13, further comprising a second insulation layer disposed on the first insulation layer, and the photoelectric conversion unit is located between the first insulation layer and the second insulation layer.

17. The sensor of claim 16, wherein:
the first insulation layer further has a second opening, and the second opening exposes the source; and
the second insulation layer has a third opening, the third opening at least partially exposes a portion of the source exposed by the second opening, and the light-shielding layer is disposed on the second insulation layer and covers the third opening to be electrically connected to the source.

18. The sensor of claim 16, further comprising a second electrode disposed on the second insulation layer, wherein the second electrode is electrically connected to the photoelectric conversion unit.

19. (canceled)

20. The sensor of claim 12, wherein the first electrode comprises a protruding portion and a contact portion connected to each other, the contact portion is in contact with the photoelectric conversion unit, and the protruding portion protrudes outward from the contact portion and is not in contact with the photoelectric conversion unit.

21. The sensor of claim 12, further comprising a transparent conductive layer, and the photoelectric conversion unit is sandwiched between the transparent conductive layer and the first electrode.

22. The sensor of claim 12, further comprising a scintillator layer located above the photoelectric conversion unit.
